(19) United States
(12) Patent Application Publication
(10) Pub. No.: US 2002/0125957 A1
(43) Pub. Date: Sep. 12, 2002

(54) PLL circuit and method for controlling the same

(76) Inventor: Masayuki Takahashi, Tokyo (JP)

Correspondence Address: SAMUEL BORODACH, Fish & Richardson P.C., 45 Rockefeller Plaza, Suite 2800, New York, NY, 10111, US

(21) Appl. No.: 10/028,596

(22) Filed: Dec. 20, 2001

(30) Foreign Application Priority Data
Dec. 22, 2000 (JP) P2000-391033

(51) Int. Cl. H03L 7/00

(52) U.S. Cl. 331/1 A

(57) ABSTRACT

A DDS 11a divides a frequency of a reference frequency signal (f₀) and supplies the frequency-divided signal to a PD 12. The PD 12 receives a phase reference signal (fᵣ) supplied from the DDS 11a as a reference phase. On the other hand, a DDS 11b sets the signal outputted from the VCO 13 to a frequency corresponding to the frequency set in the DDS 11a, and supplies this frequency-divided signal to the PD 12. The PD 12 detects the phase difference between the aforementioned phase reference signal and the frequency-divided signal and supplies the detected phase difference to the VCO 13. The VCO 13 corrects the phase fluctuation component on the basis of the detected phase difference so as to output an output signal (fᵥ) in which the frequency is kept constant.

### BACKGROUND OF THE INVENTION

1. Field of the Invention

The present invention relates to a PLL (Phase Lock Loop) circuit using DDS (Direct Digital synthesizer) and a method For controlling the PLL circuit.

2. Description of the Related Art

Conventionally, a PLL circuit has been used in a measurement apparatus For evaluating a transmission quality in a transmission system such as a transmission apparatus or a basic network adapted For a high speed digital communication system. The PLL circuit divides the frequency of a signal outputted from a VCO (Voltage Controlled Oscillator) and controls the frequency-divided signal so that both the frequency and phase of the frequency-divided signal are coincident with the frequency and phase of a reference frequency signal, respectively, whereby the PLL circuit makes the VCO output an oscillation signal of a target frequency.

FIG. 2 is a block diagram showing a configuration of a PLL circuit 10 provided with a DDS according to a related art. That is, as shown in FIG. 2, the PLL circuit 10 is constituted by the DDS 11, a PD (phase detector) 12, the VCO 13, and a frequency divider 14.

Upon reception of a reference frequency signal, the DDS 11 accumulates a desirably set phase angle in synchronism with the reference frequency signal to generate discrete waveForms of a target frequency and supply the waveForms to the PD 12 as a phase reference signal.

The PD 12 detects a phase difference between the phase reference signal inputted from the DDS 11 and a frequency-divided signal fed back from the frequency divider 14 which will be described later to supply the VCO 13 with a phase difference signal having a pulse width corresponding to the detected phase difference.

Generally, the VCO 13 detects the phase difference signal supplied from the PD 12. According to the voltage variation of the detected signal, the VCO 13 varies the oscillation frequency of its output signal and outputs a signal of a target output frequency.

The frequency divider 14 divides the frequency of the signal outputted from the VCO 13 by N, that is, to be 1/N times (N is an integer), and supplies the frequency-divided signal to the PD 12.

That is, the PLL circuit 10 is configured so that the output signal of the VCO 13 is supplied also to the frequency divider 14 by which the output signal of the VCO 13 is subjected to frequency division, that is, the frequency of the output signal of the VCO 13 is divided by N so as to be reduced to 1/N times. The frequency-divided signal obtained thus is fed back to the PD 12 so that a phase fluctuation component of the frequency-divided signal is always corrected to maintain the frequency of the output signal of the VCO 13 constant.

Next, the operation of the PLL circuit 10 will be described. The reference frequency signal (f₀) is supplied to the DDS 11 and sampled by a frequency set desirably. Then, the sampled signal is supplied, as a phase reference signal (fᵣ) to the PD 12.

On the other hand, the output signal of the VCO 13 is supplied to the frequency divider 14 and frequency-divided by a frequency dividing value N (N is an integer), so that the frequency-divided signal is supplied to the PD12.

Next, the PD 12 perForms phase-comparison between the phase reference signal received from the DDS 11 and the frequency-divided signal received from the frequency divider 14 to supply the VCO 13 with a phase difference signal having a pulse width corresponding to the phase difference. The VCO 13 outputs an output signal (fᵥ) in which a phase fluctuation component is corrected in accordance with the phase difference signal, and the frequency is maintained constant.

Next, the frequency relation between the reference frequency signal (f₀) and the output signal (fᵥ) in the PLL circuit 10 is shown in the following equation [2].

$${f}_{0} \times \frac{D}{{2}^{k}} = \frac{{f}_{v}}{N} ⇔ {f}_{v} = {f}_{0} \times \frac{D}{{2}^{k}} \times N \qquad [ 2 ]$$

Here, f₀ is the frequency of the reference frequency signal, fᵥ is the frequency of the output signal, N is a dividing value in the frequency divider 14, D is a frequency setting value in the DDS 11, and k is the number of bits of the setting resolution of the DDS 11.

Specific numerical values are substituted in the equation [2] to calculate a setting value D. For example, in a case where the output signal fᵥ=101 Hz is led out from the reference frequency signal f₀=10 Hz, the value of D is set to satisfy the following equation:

$$10 \times \frac{D}{{2}^{k}} = \frac{101}{N} ⇔ D = ( \frac{10}{101} ) \times N \times {2}^{k}$$

Here, in accordance with the characteristic of the DDS 11, D<2^{k-1} and N is an integer. Accordingly, in order to make the frequency of the phase reference signal (fᵣ) high (For example,

$${f}_{r} = 4 Hz ) , if N = ( \frac{101}{4} ) ≅ 25 ,$$

the setting value D is determined as follows:

$$D = ( \frac{10}{101} ) \times 25 \times {2}^{k}$$

In such a PLL circuit 10 according to the related art, since it is necessary to set the frequency setting value (D) of the DDS 11 to an integer, there occurs a frequency error in the frequency of the output signal (fᵥ) inevitably due to such an operation of setting the frequency setting value (D) to an integer.

Accordingly, for example, if a low speed reference frequency signal (For example, 1.544 MHz) is synchronized with a high speed transmission signal (For example, 10 GHz band) in SDH (Synchronous Digital Hierarchy), even a slight frequency error may cause a bit error. Specifically, even in a case where a reference frequency signal and an output signal are synchronized with each other, if there is an error of +0.1 ppm in frequency, data of 10⁷+1 are transmitted in the period of time in which data of 10⁷ are supposed to be transmitted originally.

Further, in accordance with a setting value of the DDS 11, in the output signal from the DDS 11, there may occur spurious emission which is an unnecessary frequency component other than a desired frequency, due to non-linearity, quantization error, or the like of a D/A converter in the DDS 11. Although such spurious emission can be avoided by changing the setting value of the DDS 11, the setting value of the DDS 11 is determined by only one value with respect to the frequency of the output signal in connection with the above-mentioned equation [2]. Therefore, in the case where spurious emission occurs in such setting made for the DDS 11, if the setting value is changed, the output signal contains a frequency error.

As means for avoiding spurious emission, for example, there is a method in which a plurality of reference frequencies are prepared and one is selected from the prepared reference frequencies to avoid the spurious emission, like the DDS as disclosed in Japanese Utility Patent No. 2572244. However, the preparation of a plurality of reference frequencies may make the circuit scale large and become disadvantageous in cost.

### SUMMARY OF THE INVENTION

An object of the invention is to provide a PLL circuit in which a frequency error in an output signal is reduced with respect to a reference signal and less spurious emission occurs in the output signal, and to provide a method for controlling the PLL circuit.

According to a first aspect of the present invention, there is provided a PLL circuit comprising:

a clock generation circuit (for example, DDS 11a as shown in FIG. 1) for generating a clock signal having a desired oscillation frequency from a reference input signal and outputting the generated clock signal;

a phase detection circuit (for example, PD 12 as shown in FIG. 1) for detecting a phase difference between the clock signal outputted from the clock generation circuit and an output feedback signal to output a phase difference signal;

a control circuit (for example, VCO 13 as shown in FIG. 1) for controlling an oscillation frequency of an output signal of the control circuit on a basis of the phase difference signal outputted from the phase detection circuit;

a frequency dividing circuit (for example, DDS 11b as shown in FIG. 1) for dividing a frequency of the output signal outputted from the control circuit to output, as the output feedback signal, a frequency-divided signal having an oscillation frequency corresponding to the oscillation frequency of the clock signal,

wherein each of the clock generation circuit and the frequency dividing circuit is a direct digital synthesizer circuit for generating a signal corresponding to a desired oscillation frequency.

According to the first aspect of the present invention, in the PLL circuit: the clock generation circuit generates a clock signal of a desired oscillation frequency from a reference input signal and outputs the generated clock signal; the phase detection circuit detects a phase difference between the clock signal outputted from the clock generation circuit and an output feedback signal and outputs a phase difference signal; the control circuit controls an oscillation frequency of an output signal based on the phase difference signal outputted from the phase detection circuit; and the frequency dividing circuit divides a frequency of the output signal outputted from the control circuit and outputs, as the output feedback signal, a frequency-divided signal of an oscillation frequency corresponding to the oscillation frequency of the clock signal. Accordingly, even if each of the setting value of the oscillation frequency set in the clock generation circuit and the setting value of the oscillation frequency set in the frequency dividing circuit is set as an integer value, in case that the ratio between the setting values is equivalent to the ratio between the frequency of the reference input signal and the oscillation frequency of the output signal, the output signal outputted from the control circuit has no frequency error. That is, it is possible to output an output signal having a correct frequency.

Further, each of the clock generation circuit and the frequency dividing circuit is configured by a direct digital synthesizer circuit for generating a signal corresponding to a desired oscillation frequency. Accordingly, if the setting values of the oscillation frequencies set in the clock generation circuit and the frequency dividing circuit are changed, the oscillation frequency of the output signal outputted from the control circuit can be changed desirably. Further, by the high resolution performance of the direct digital synthesizer circuit, it is possible to set more accurate oscillation frequency.

According to a second aspect of the present invention, there is provided the PLL circuit according to the first aspect of the invention, wherein a ratio of an oscillation frequency of an output signal outputted from the control circuit to an oscillation frequency of an input signal inputted to the clock generation circuit and another ratio of a setting value of an oscillation frequency of the frequency dividing circuit to a setting value of an oscillation frequency of the clock generation circuit meet the following equation [1]:

$$\frac{{f}_{v}}{{f}_{0}} = \frac{{D}_{a}}{{D}_{b}} \qquad [ 1 ]$$

here, fᵥ represents the oscillation frequency of the output signal, fₒ represents the oscillation frequency of the input signal, Dₐ represents a the setting value of the oscillation frequency of the clock generation circuit and D_{b} represents the setting value of the oscillation frequency of the frequency dividing circuit.

According to the second aspect of the present invention, the ratio of the oscillation frequency of the input signal inputted to the clock generation circuit to the oscillation frequency of the output signal outputted from the control circuit and another ratio of the setting value of the oscillation frequency set by the clock generation circuit to the setting value of the oscillation frequency set by the frequency dividing circuit have a correspondence relation as shown by the equation [1]. Accordingly, it is possible to select a combination of the setting values Dₐ and D_{b} freely with respect to the frequency of the output signal (fᵥ). Even if spurious emission occurs, it is possible to avoid the spurious emission by changing the setting values Dₐ and D_{b} without having any frequency error of the output signal and without expanding the circuit scale.

According to a third aspect of the invention, there is provided the PLL circuit according to the second aspect of the invention, wherein when spurious emission is generated in the output signal, the setting values of the oscillation frequencies set of the clock generation circuit and the frequency dividing circuit are changed, respectively, while satisfying the equation [1].

In the third aspect of the present invention, in a case where spurious emission occurs in the output signal, the two setting values of the oscillation frequencies of the clock generation circuit and the frequency dividing circuit are changed while the correspondence relationship shown by the above-mentioned equation [1] is maintained as it is. Accordingly, the spurious emission can be avoided without making any change in the oscillation signal of the output signal.

### BRIEF DESCRIPTION OF THE DRAWINGS

FIG. 1 is a block diagram showing a configuration of an embodiment of the PLL circuit 1 to which the present invention is applied.

FIG. 2 is a block diagram showing a configuration of a PLL circuit 10 according to the related art.

### DETAILED DESCRIPTION OF THE PREFERRED EMBODIMENTS

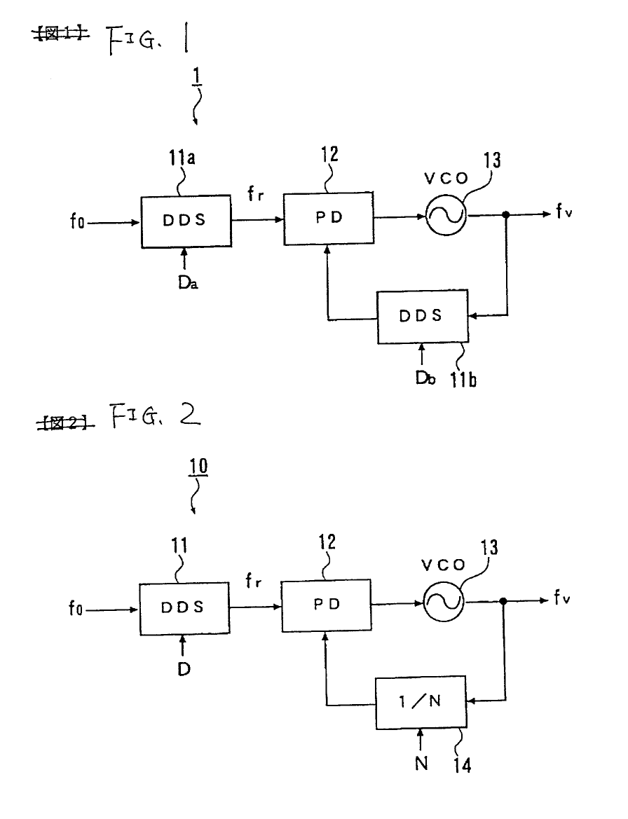

Hereunder, an embodiment of the present invention will be described in detail with reference to FIG. 1.

FIG. 1 is a view showing an embodiment of a PLL circuit 1 to which the present invention is applied.

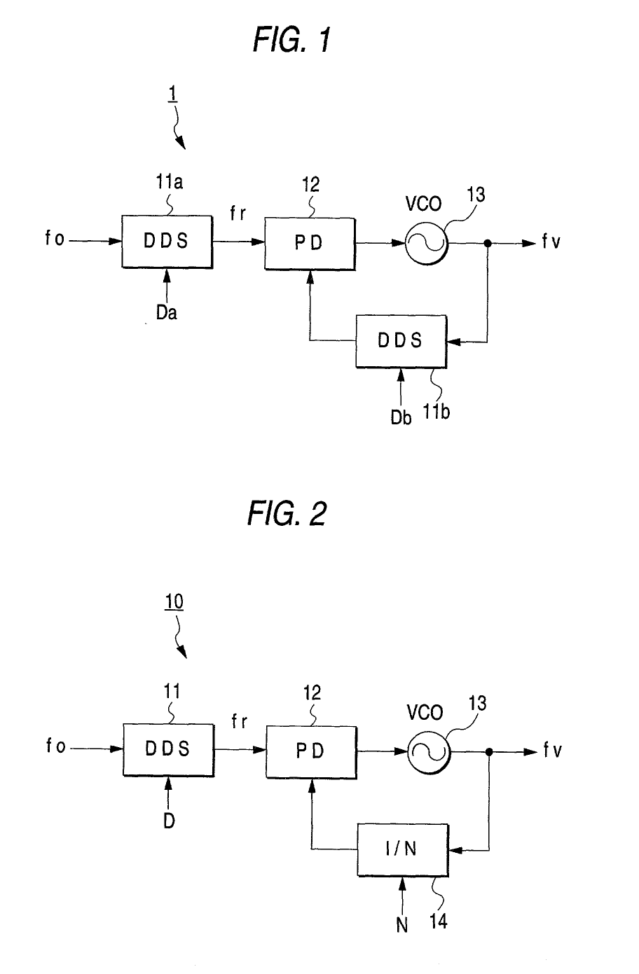

First, the configuration is described. Incidentally, in FIG. 1, the same members as those shown in FIG. 2 in the description of the PLL circuit 10 according to the related art are referenced correspondingly and duplicate description on the same member will be omitted here.

As shown in FIG. 1, the PLL circuit 1 is constituted by a couple of DDSs 11a and 11b, a PD 12, and a VCO 13.

The PLL circuit 1 according to the embodiment of the present invention shown in FIG. 1 is different from the PLL circuit 10 according to the related art as shown in FIG. 2 mainly in a point that the frequency divider 14 is replaced with the DDS 11b. That is, the DDS 11b divides the frequency of the signal supplied from the VCO 13 by a desired setting value and a divided-frequency signal is supplied to the PD 12.

A frequency relationship between the reference frequency signal (f0) and the output signal (fᵥ) in the PLL circuit 1 according to the embodiment of the present invention is shown in the equation [1].

$${f}_{0} \times \frac{{D}_{a}}{{2}^{k}} = {f}_{v} \times \frac{{D}_{b}}{{2}^{k}} ⇔ \frac{{f}_{v}}{{f}_{0}} = \frac{{D}_{a}}{{D}_{b}} \qquad [ 1 ]$$

Here, f₀ designates the frequency of the reference frequency signal, fᵥ designates the frequency of the output signal, Dₐ designates the frequency setting value (positive integer) of the DDS 11a, D_{b} designates the frequency setting value (positive integer) of the DDS 11b, and k designates the number of bits of setting resolution of each of the DDSs 11a and 11b (the DDSs 11a and 11b are equal in the number of bits to each other).

In the PLL circuit 1 in this embodiment of the present invention, as shown in the above-mentioned equation [1], the frequency setting values Dₐ and D_{b} are set so that the ratio of the output signal (fᵥ) to the reference frequency signal (f₀) is equal to the ratio of the frequency setting value Dₐ of the DDS 11a to the frequency setting value D_{b} of the DDS 11b.

Specific numerical values are substituted to the equation [1] to calculate the setting values Dₐ and D_{b}. For example, in a case where an output signal fᵥ=101 Hz is obtained from a reference frequency signal f₀=10 Hz in the PLL circuit 1, Dₐ and D_{b} are set so that the following equations are satisfied.

$$10 \times ( \frac{{D}_{a}}{{2}^{k}} ) = 101 \times ( \frac{{D}_{b}}{{2}^{k}} ) ⇔ \frac{101}{10} = \frac{{D}_{a}}{{D}_{b}}$$

Assuming here that Dₐ, D_{b}<2^{k-1} and k=10 (each DDS having 10 bits), it will go well if Dₐ and D_{b} may be smaller than 512.

Accordingly, the combinations of possible values of Dₐ and D_{b} are as follows.

Dₐ=202, D_{b}=20

Dₐ=303, D_{b}=30

Dₐ=404, D_{b}=40

Dₐ=505, D_{b}=50

Here, in order to improve the characteristic of the PLL, it will do to make the frequency of the phase reference signal (fᵣ) high. Accordingly, if the setting values are D_{b}=50 and Dₐ=505, the frequency value of the phase reference signal (fᵣ) is as follows.

$$10 \times ( \frac{505}{{2}^{10}} ) = 101 ( \frac{50}{{2}^{10}} ) ⇔ \frac{5050}{{2}^{10}} ≅ 4.93 Hz$$

Accordingly, the PLL circuit can be constituted with a phase reference signal (fᵣ) of a frequency equivalent to a PLL circuit 10 using a DDS according to the related art. While the performance of C/N ratio is maintained substantially equivalent, a signal containing no error with respect to a desired reference frequency signal (f₀)=10 Hz is outputted as the output signal (fᵥ). Further, if the setting values (For example, Dₐ=505 and D_{b}=50) generate spurious emission which excesses a level allowable in the output signal, it is possible to avoid the spurious emission without having any frequency error in the output signal, for example, by setting the setting values for Dₐ=404 and D_{b}=40.

As described above, according to the embodiment of the present invention, the DDS 11a divides the frequency of the reference frequency signal (f0) and supplies the frequency-divided signal to the PD 12. The PD 12 receives a phase reference signal (fᵣ) supplied from the DDS 11a as a reference phase. On the other hand, the DDS 11b sets the signal outputted from the VCO 13 to a frequency corresponding to the frequency set in the DDS 11a, and supplies this frequency-divided signal to the PD 12. The PD 12 detects the phase difference between the aforementioned phase reference signal and the frequency-divided signal and supplies the detected phase difference to the VCO 13. The VCO 13 corrects the phase fluctuation component on a basis of the detected phase difference so as to output an output signal (fᵥ) in which the frequency is kept constant.

Accordingly, it will go well if the setting values Dₐ and D_{b} of the DDSs 11a and 11b are set so that the ratio (Dₐ/D_{b}) is equal to the ratio (fᵥ/f₀) in which f₀ is the frequency of the reference signal and fᵥ is the frequency of the output signal. Thus, even if the setting values Dₐ and D_{b} are set to integers, the output signal (fᵥ) having no frequency error can be outputted. That is, the output signal (fᵥ) with a correct frequency can be outputted.

By changing the setting values of the DDSs 11a and 11b, the frequency of the output signal (fᵥ) which is outputted from the VCO 13 can be changed desirably. Further, due to the high resolution performance of the DDSs 11a and 11b, more highly accurate frequency setting can be conducted.

Further, with respect to the frequency of the output signal (fᵥ), any combination of the setting values Dₐ and D_{b} can be selected freely. Accordingly, even when spurious emission is generated, such spurious emission can be avoided only by changing the setting values without expanding the circuit scale, without generating any frequency error in the output signal, and without changing the frequency per se.

Incidentally, the present invention is not limited to the contents of the above embodiments, but may be modified appropriately without departing the gist of the present invention.

In the PLL circuit according to the first aspect of the present invention and in the method for controlling the PLL circuit according to the fourth aspect of the present invention, even if both the setting value of the oscillation frequency set by a clock generation circuit and the setting value of the oscillation frequency set by a frequency dividing circuit are set to integers, no frequency error is contained in the output signal outputted from a control circuit when the ratio between the two setting values is coincident with the ratio of the frequency of the reference input signal to the oscillation frequency of the output signal. Thus, an output signal of a correct and stable frequency can be outputted.

Further, by changing the setting value of the oscillation frequency set by a clock generation circuit and the setting value of the oscillation frequency set by a frequency dividing circuit, the oscillation frequency of the output signal outputted from the control circuit can be changed desirably. Further, with the high resolution performance of the direct digital synthesizer circuit, a more accurate oscillation frequency can be set.

In the PLL circuit according to the second aspect of the present invention, with respect to the frequency of the output signal (fᵥ), a combination of the setting values Dₐ and D_{b} can be selected freely. Accordingly, even when spurious emission is generated, such spurious emission can be avoided by changing the setting values Dₐ and D_{b} without expanding the circuit scale and without providing any frequency error in the output signal.

In the PLL circuit according to the third aspect of the present invention, even when spurious emission is generated, the spurious emission can be avoided without changing the oscillation frequency in the output signal.

What is claimed is:

1. A PLL circuit comprising:
a clock generation circuit for generating a clock signal having a desired oscillation frequency from a reference input signal and outputting the generated clock signal;
a phase detection circuit for detecting a phase difference between the clock signal outputted from the clock generation circuit and an output feedback signal to output a phase difference signal;
a control circuit for controlling an oscillation frequency of an output signal of the control circuit on a basis of the phase difference signal outputted from the phase detection circuit; and
a frequency dividing circuit for dividing a frequency of the output signal outputted from the control circuit to output, as the output feedback signal, a frequency-divided signal having an oscillation frequency corresponding to the oscillation frequency of the clock signal,
wherein each of the clock generation circuit and the frequency dividing circuit is a direct digital synthesizer circuit for generating a signal corresponding to a desired oscillation frequency.

2. The PLL circuit according to claim 1, wherein a ratio of an oscillation frequency of an output signal outputted from the control circuit to an oscillation frequency of an input signal inputted to the clock generation circuit and another ratio of a setting value of an oscillation frequency of the frequency dividing circuit to a setting value of an oscillation frequency of the clock generation circuit meet the following equation [1]:
$$\frac{{f}_{v}}{{f}_{0}} = \frac{{D}_{a}}{{D}_{b}} \qquad [ 1 ]$$
here, fᵥ represents the oscillation frequency of the output signal, fₒ represents the oscillation frequency of the input signal, Dₐ represents a the setting value of the oscillation frequency of the clock generation circuit and D_{b} represents the setting value of the oscillation frequency of the frequency dividing circuit.

3. The PLL circuit according to claim 2, wherein when spurious emission is generated in the output signal, the setting values of the oscillation frequencies set of the clock generation circuit and the frequency dividing circuit are changed, respectively, while satisfying the equation [1].

4. A method for controlling a PLL circuit comprising the steps of:
generating a clock signal corresponding to a desired oscillation frequency from a reference input signal to output the generated clock signal;
detecting a phase difference between the clock signal and an output feedback signal to output a detected phase difference signal;
controlling an oscillation frequency of an output signal based on the phase difference signal;
dividing a frequency of the output signal outputted in the control step to output, as the output feedback signal, a frequency-divided signal of an oscillation frequency corresponding to the oscillation frequency of the clock signal
setting a setting value Dₐ for the generating step and a setting value D_{b} for the dividing step so that the setting values Dₐ, D_{b} and the an oscillation signal of the reference input signal f₀ and an oscillation signal of the output signal in the controlling step fᵥ meet the following equation [1].
$$\frac{{f}_{v}}{{f}_{0}} = \frac{{D}_{a}}{{D}_{b}} \qquad [ 1 ]$$
